(19) United States
(12) Patent Application Publication
(10) Pub. No.: US 2009/0185349 A1
(43) Pub. Date: Jul. 23, 2009

(54) ELECTRONIC APPARATUS

(75) Inventor: Yukihiko HATA, Hamura-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/345,360

(22) Filed: Dec. 29, 2008

(30) Foreign Application Priority Data
Jan. 17, 2008 (JP) 2008-008287

(51) Int. Cl. H05K 7/20

(52) U.S. Cl. 361/697; 361/695

(57) ABSTRACT

According to one embodiment, a fan case of a cooling fan includes first and second exhaust openings separately provided in two side surface portions. The first exhaust opening and the second exhaust opening are arranged in a rotational direction of a fan blade in the order named. A first heating element has a heating value greater than that of a second heating element. A first heat radiating member is thermally connected to the first heating element through a first heat transfer member and opposed to the first exhaust opening of the cooling fan. A second heat radiating member is thermally connected to the second heating element through a second heat transfer member and opposed to the second exhaust opening of the fan.

### CROSS-REFERENCE TO RELATED APPLICATIONS

This application is based upon and claims the benefit of priority from Japanese Patent Application No. 2008-008287, filed Jan. 17, 2008, the entire contents of which are incorporated herein by reference.

### BACKGROUND

1. Field

One embodiment of the present invention relates to an electronic apparatus provided with a cooling fan.

2. Description of the Related Art

An electronic apparatus, such as a portable computer, is provided with a cooling fan for cooling a heating element mounted in a housing. Some cooling fans each have two exhaust openings that are separately provided in two adjacent side surface portions of a fan case.

A cooling device that includes a cooling fan provided with two exhaust openings is disclosed in Jpn. Pat. Appln. KOKAI Publication No. 2004-31606. In this cooling device, at least one heat pipe is provided corresponding to each exhaust opening of the cooling fan. A heat radiating member is provided on an end portion of each heat pipe so as to face the exhaust opening of the cooling fan.

In recent years, there is a tendency toward a further increase in the heating value of heating elements that are mounted in electronic apparatuses, such as portable computers. Thus, cooling devices that are mounted in these electronic apparatuses are expected to have a cooling performance as high as possible.

Under this requirement, the cooling device described in the aforesaid patent document cannot be a satisfactory system, thus there is a demand for a cooling device with further improved cooling performance.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the invention;

FIG. 2 is an exemplary perspective view showing an example of a cooling fan according to the first embodiment of the invention;

FIG. 3 is an exemplary plan view showing the example of the cooling fan according to the first embodiment of the invention;

FIG. 4 is an exemplary plan view showing an example of the cooling fan according to the first embodiment of the invention;

FIG. 5 is an exemplary sectional view of the portable computer shown in FIG. 1;

FIG. 6 is an exemplary enlarged sectional view of the cooling fan and its surroundings shown in FIG. 5;

FIG. 7 is an exemplary sectional view of a modification of the portable computer according to the first embodiment of the invention;

FIG. 8 is an exemplary sectional view of a portable computer according to a second embodiment of the invention;

FIG. 9 is an exemplary sectional view of a portable computer according to a third embodiment of the invention;

FIG. 10 is an exemplary sectional view of a portable computer according to a fourth embodiment of the invention;

FIG. 11 is an exemplary enlarged sectional view of the cooling fan and its surroundings shown in FIG. 10;

FIG. 12 is an exemplary sectional view of a modification of the portable computer according to the fourth embodiment of the invention;

FIG. 13 is an exemplary sectional view of a portable computer according to a fifth embodiment of the invention; and

FIG. 14 is an exemplary sectional view of a portable computer according to a sixth embodiment of the invention.

### DETAILED DESCRIPTION

Various embodiments according to the invention will be described hereinafter with reference to the accompanying drawings. In general, according to one embodiment of the invention, an electronic apparatus comprises (i) a housing, (ii) a first heating element mounted in the housing, (iii) a second heating element mounted in the housing, (iv) a cooling fan contained in the housing and provided with a fan case and a fan blade configured to rotate in the fan case, (v) a first heat radiating member contained in the housing, (vi) a second heat radiating member contained in the housing, (vii) a first heat transfer member extending between the first heat radiating member and the first heating element, and (viii) a second heat transfer member extending between the second heat radiating member and the second heating element. The fan case of the cooling fan includes two adjacent side surface portions and first and second exhaust openings separately provided in the two side surface portions. The first exhaust opening and the second exhaust opening are arranged in a rotational direction of the fan blade in the order named. The first heating element has a heating value greater than that of the second heating element. The first heat radiating member is thermally connected to the first heating element through the first heat transfer member and opposed to the first exhaust opening of the cooling fan. The second heat radiating member is thermally connected to the second heating element through the second heat transfer member and opposed to the second exhaust opening of the cooling fan.

Embodiments of the present invention applied to portable computers will now be described with reference to the accompanying drawings.

### First Embodiment

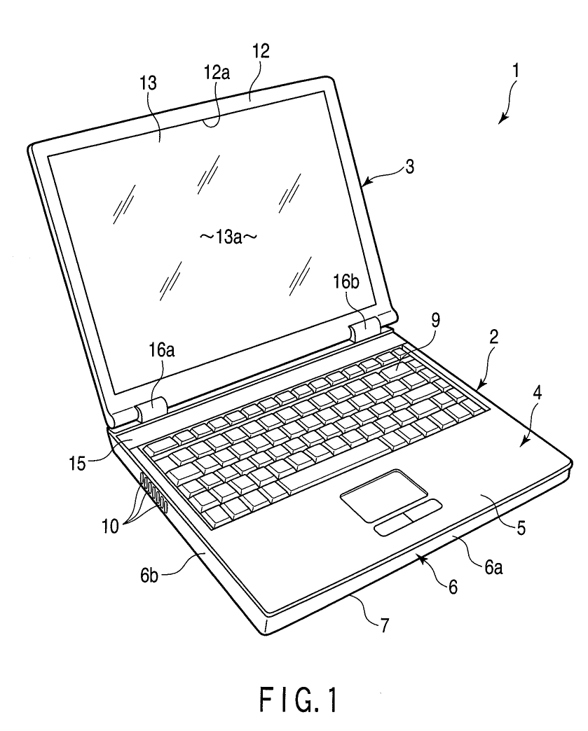

FIGS. 1 to 6 show a portable computer 1 as an electronic apparatus according to a first embodiment of the invention. As shown in FIG. 1, the portable computer 1 is provided with a main unit 2, for use as an apparatus main body, and a display unit 3.

The main unit 2 is provided with a box-shaped housing 4. The housing 4 includes a top wall 5, a peripheral wall 6, and a bottom wall 7. The top wall 5 supports a keyboard 9. As shown in FIGS. 1 and 5, the peripheral wall 6 includes a front wall portion 6a, left sidewall portion 6b, right sidewall portion 6c, and rear wall portion 6d. The rear wall portion 6d is to face the side opposite from a user who operates the apparatus. The left and right sidewall portions 6b and 6c individually adjoin the rear wall portion 6d, and in cooperation with the rear wall portion 6d, define a corner portion C in the housing 4. As shown in FIG. 5, the rear wall portion 6d and the left sidewall portion 6b are each provided with, for example, a plurality of air vents 10.

As shown in FIG. 1, the display unit 3 is provided with a display housing 12 and a display device 13 contained therein. The display device 13 includes a display screen 13a. The display screen 13a is exposed to the outside of the display housing 12 through an opening part 12a in the front face of the housing 12.

As shown in FIG. 1, a rear housing end portion 15, which is one end portion of the housing 4, is provided with, for example, a pair of hinge parts 16a and 16b. The rear housing end portion 15 is to be situated farthest, among all other end portions of the housing 4, from the user who operates the apparatus. The rear wall portion 6d forms a part of the rear housing end portion 15.

The display unit 3 is supported on the rear housing end portion 15 by the hinge parts 16a and 16b. The display unit 3 is rockable between a first posture (i.e., closed position) in which it is laid to cover the housing 4 from above and a second posture (i.e., open position) in which it is raised with respect to the housing 4.

As shown in FIG. 5, a circuit board 21 is contained in the housing 4. First and second heating elements 22 and 23 are mounted on the circuit board 21. The heating elements 22 and 23 are electronic components that generate heat when activated. A CPU, graphic chip, north bridge (trademark), memory, etc., are specific examples of the heating elements 22 and 23, respectively. The heating elements stated herein are not limited to these examples, but may be any of various components that are expected to generate heat.

The first heating element 22 has a heating value greater than that of the second heating element 23. In other words, the energy consumption of the first heating element 22 is higher than that of the second heating element 23.

As shown in FIG. 5, a cooling device 24 for accelerating cooling of the heating elements 22 and 23 is mounted in the housing 4. The cooling device 24 includes a cooling fan 25, first and second heat radiating members 26 and 27, and first and second heat transfer members 28 and 29. The cooling fan 25, first and second heat radiating members 26 and 27, and first and second heat transfer members 28 and 29 are contained in the housing 4.

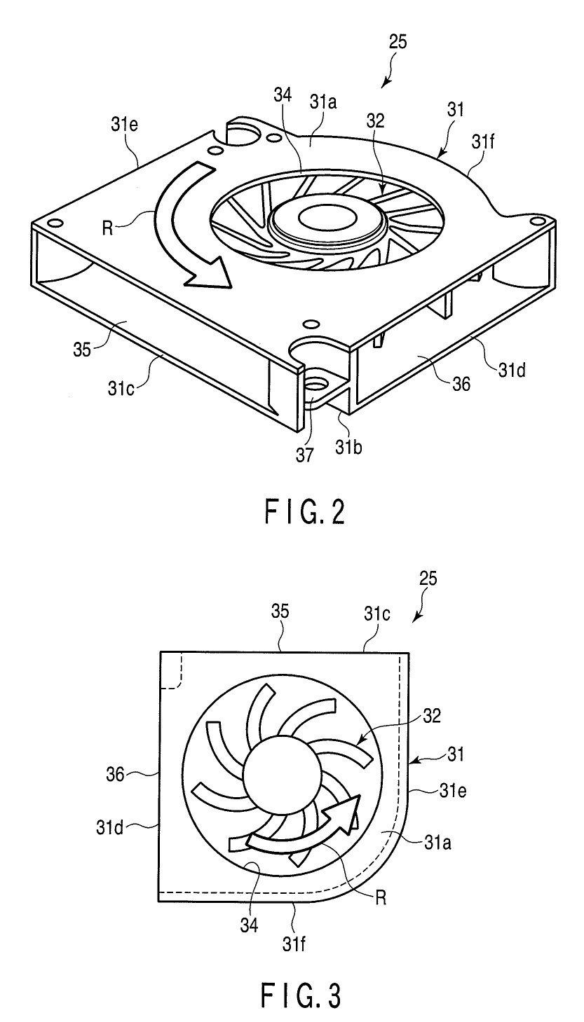

The cooling fan 25 will now be described in detail with reference to FIGS. 2 to 4. The cooling fan 25 is a centrifugal cooling fan, which is provided with a fan case 31 and fan blades 32 that are configured to rotate in the fan case 31. As shown in FIG. 2, the fan case 31 includes a top surface portion, a lower surface portion, and four side surface portions 31c, 31d, 31e and 31f, and is formed in the shape of a box that partially includes an arcuate portion. The top and bottom surface portions 31a and 31b are each provided with an intake opening 34.

As shown in FIG. 2, the fan case 31 has two exhaust openings 35 and 36. The two exhaust openings 35 and 36 are separately provided in the two adjacent side surface portions 31c and 31d of the fan case 31. The two side surface portions 31c and 31d according to the present embodiment adjoin each other with, for example, a screw mounting portion 37 between them.

The “two adjacent side surface portions” stated herein are not supposed to be two opposite side surface portions, that is, they are “two non-opposite side surface portions”. Thus, the “two adjacent side surface portions” according to the present invention are not limited to two continuous side surface portions, but also include two side surface portions between which a screw mounting portion or some other structure is interposed.

The cooling fan 25 is configured so that the ambient air is drawn into the fan case 31 through the intake openings 34 as the fan blades 32 are rotated and the drawn-in air is discharged through the first and second exhaust openings 35 and 36. The cooling fan 25 has such an operation region that its air delivery rate is higher than that of a cooling fan of the same size that is provided with only one exhaust opening, for example.

As shown in FIG. 2, the two exhaust openings 35 and 36 are defined as first and second exhaust openings 35 and 36, respectively. The first and second exhaust openings 35 and 36 are arranged in a rotational direction R of the fan blades 32 in the order named.

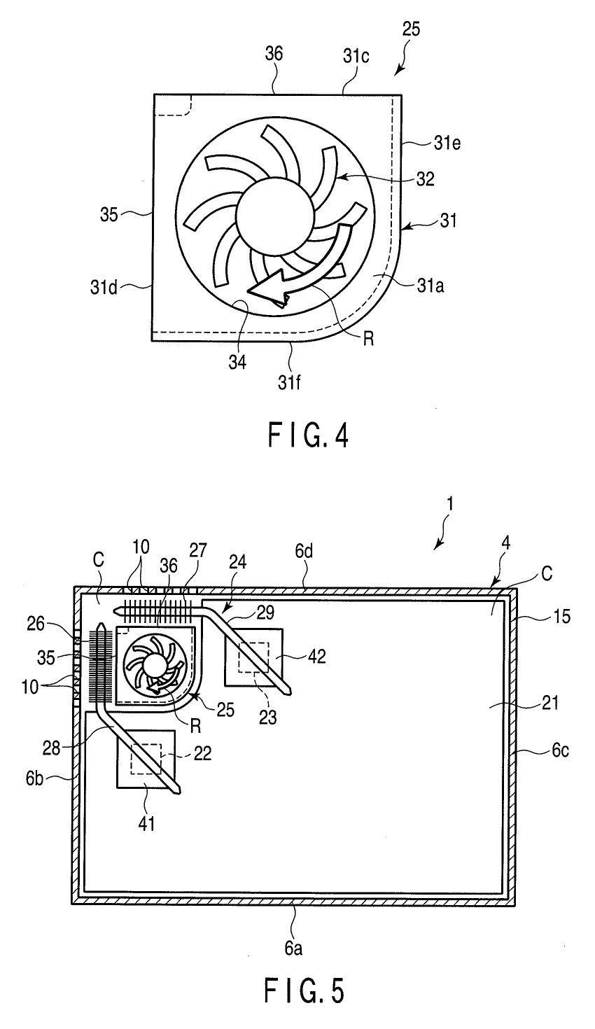

Thus, in a left-hand (i.e., counterclockwise) version of the cooling fan 25, such as the one shown in FIG. 3, the first and second exhaust openings 35 and 36 are left-handedly arranged in the order named. In a right-hand (i.e., clockwise) version of the cooling fan 25, such as the one shown in FIG. 4, on the other hand, the first and second exhaust openings 35 and 36 are right-handedly arranged in the order named.

For example, the first exhaust opening 35 is larger than the second exhaust opening 36. In an example of the cooling fan 25, the second exhaust opening 36 may be opened nearly as large as the first exhaust opening 35. According to this cooling fan 25, the rate of air delivery through the second exhaust opening 36 is also higher, so that the synthetic air delivery rate of the fan 25 is higher.

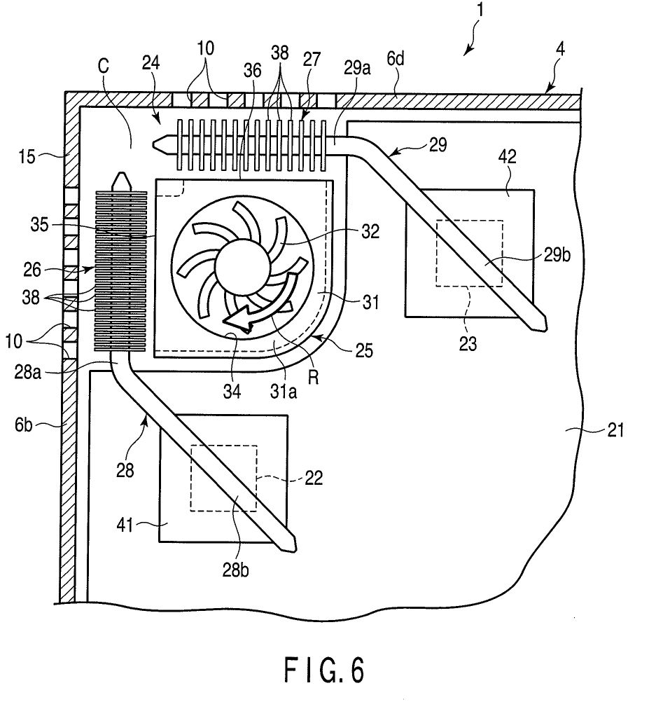

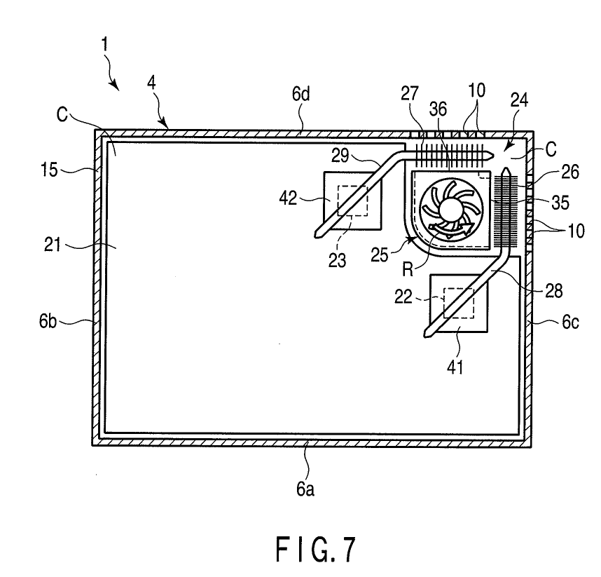

The portable computer 1 provided with the right-hand cooling fan 25 according to the present embodiment will now be representatively described in detail with reference to FIGS. 5 and 6. FIG. 7 shows a modification of the present embodiment provided with the left-hand cooling fan 25. The same function and effect of the portable computer 1, which will be described later, can also be obtained with this arrangement.

As shown in FIG. 5, the cooling fan 25 is located, for example, in the corner portion C in the housing 4 that is defined by the rear wall portion 6d and the left sidewall portion 6b of the housing 4. The first exhaust opening 35 of the fan 25 is opposed to the air vents 10 in the sidewall portion 6b of the housing 4. The second exhaust opening 36 of the fan 25 is opposed to the air vents 10 in the rear wall portion 6d of the housing 4.

As shown in FIG. 6, the first heat radiating member 26 is located between the first exhaust opening 35 of the cooling fan 25 and the air vents 10 in the sidewall portion 6b and opposed to the first exhaust opening 35 of the fan 25. The second heat radiating member 27 is located between the second exhaust opening 36 of the fan 25 and the air vents 10 in the rear wall portion 6d and opposed to the second exhaust opening 36 of the fan 25.

The first heat radiating member 26 is lower in, for example, heat resistance than the second heat radiating member 27. The “lower in heat resistance” implies good thermal conductivity and higher liability to heat dissipation. The heat resistance is inversely proportional to, for example, the surface area of a heat radiating member.

The first and second heat radiating members 26 and 27 are fin units that each include, for example, a plurality of fins 38. The fins 38 of the first heat radiating member 26 are arranged, for example, at pitches narrower than those of the second heat radiating member 27. Thus, the first heat radiating member 26 is greater in surface area and lower in heat resistance than the second heat radiating member 27.

As shown in FIG. 6, a first heat receiving member 41 is thermally connected to the first heating element 22. The first heat transfer member 28 extends between the first heat radiating member 26 and the first heating element 22. More specifically, the first heat transfer member 28 includes a heat radiating portion 28a and a heat receiving portion 28b, which are connected to the first heat radiating member 26 and the first heat receiving member 41, respectively.

Thus, the first heat radiating member 26 is thermally connected to the first heating element 22 through the first heat transfer member 28. The first heat transfer member 28 receives, at its heat receiving portion 28b, some of the heat generated by the first heating element 22, and transfers the received heat to the first heat radiating member 26.

As shown in FIG. 6, a second heat receiving member 42 is thermally connected to the second heating element 23. The second heat transfer member 29 extends between the second heat radiating member 27 and the second heating element 23. More specifically, the second heat transfer member 29 includes a heat radiating portion 29a and a heat receiving portion 29b, which are connected to the second heat radiating member 27 and the second heat receiving member 42, respectively.

Thus, the second heat radiating member 27 is thermally connected to the second heating element 23 through the second heat transfer member 29. The second heat transfer member 29 receives, at its heat receiving portion 29b, some of the heat generated by the second heating element 23, and transfers the received heat to the second heat radiating member 27.

The first and second heat transfer members 28 and 29 are, for example, heat pipes that each include a container and a working fluid sealed therein. The heat transfer members 28 and 29, which are heat pipes, transfer heat between their heat receiving and radiating portions by utilizing heat of vaporization and capillarity.

The following is a description of the operation of the portable computer 1.

When the portable computer 1 is activated, the first and second heating elements 22 and 23 individually generate heat. Much of the heat generated by the first heating element 22 is transferred to the first heat radiating member 26 by the first heat transfer member 28. Much of the heat generated by the second heating element 23 is transferred to the second heat radiating member 27 by the second heat transfer member 29.

The first and second exhaust openings 35 and 36 of the cooling fan 25 are arranged in the rotational direction of the fan blades 32 in the order named. As the fan blades 32 rotate, therefore, air that is compressed in the fan case 31 is first released through the first exhaust opening 35 and then through the second exhaust opening 36. Accordingly, the quantity of air discharged through the first exhaust opening 35 is generally greater than that of air discharged through the second exhaust opening 36. Thus, cooling of the first heat radiating member 26 that is opposed to the first exhaust opening 35 can be accelerated more easily than that of the second heat radiating member 27 opposed to the second exhaust opening 36.

In the present embodiment, the first heat radiating member 26 that is thermally connected to the first heating element 22 with a relatively large heating value is opposed to the first exhaust opening 35, while the second heat radiating member 27 that is thermally connected to the second heating element 23 with a relatively small heating value is opposed to the second exhaust opening 36. Thus, cooling of the first heating element 22 can be accelerated more easily than that of the second heating element 23, so that the first heating element 22 can be less easily heated to an excessively high temperature than the second heating element 23.

The portable computer 1 constructed in this manner is capable of operating a high cooling performance. Specifically, in the portable computer 1, the first heat radiating member 26 that is thermally connected to the first heating element 22 with a relatively large heating value is opposed to the first exhaust opening 35, of the first and second exhaust openings 35 and 36 that are arranged in the rotational direction of the fan blades 32 in the order named. Further, the second heat radiating member 27 that is thermally connected to the second heating element 23 with a relatively small heating value is opposed to the second exhaust opening 36.

Thus, the first heating element 22 with a relatively large heating value is made to correspond to the first exhaust opening 35 with a relatively high air delivery rate, while the second heating element 23 with a relatively small heating value is made to correspond to the second exhaust opening 36 with a relatively low air delivery rate. By doing this, the capacity of the cooling fan 25 can be utilized more efficiently, and the cooling efficiency of the portable computer 1 as a whole can be intended to be optimized. In consequence, the portable computer 1 can achieve a high cooling performance.

If the first heat radiating member 26 is lower in heat resistance than the second heat radiating member 27, a relatively large air delivery through the first exhaust opening 35 can be used more effectively, and the capacity of the cooling fan 25 can be utilized more efficiently. Thus, the portable computer 1 can achieve a higher cooling performance.

If the first heat radiating member 26 is a fin unit of which the fins 38 are arranged at pitches narrower than those of the second heat radiating member 27, the first heat radiating member 26 that is lower in heat resistance than the second heat radiating member 27 can be obtained with a relatively simple structure.

The first and second heat radiating members of the present invention are not limited to those fin units. For example, fin units of a copper alloy and an aluminum alloy may be used as the first and second heat radiating members, respectively, mutually with the same pitches. Since the copper alloy is higher in thermal conductivity than the aluminum alloy, in this case, the heat resistance of the first heat radiating member is lower than that of the second heat radiating member.

The present invention is not limited to the arrangement described above, and the first and second heat radiating members may be configured to share the same heat resistance. For example, a fin unit with fin pitches as narrow as those of the first heat radiating member may be used as the second heat radiating member. In general, however, heat radiating members with narrower fin pitches or copper-alloy versions with reduced heat resistance, for example, have many disadvantages, including higher prices and greater weights, as compared with heat radiating members with higher heat resistance.

According to the one embodiment of the present invention, from this point of view, the first heat radiating member 26 with a preferentially increased cooling efficiency is made to correspond to the first exhaust opening 35 with a relatively high air delivery rate, whereby cooling of the first heating element 22 with a relatively large heating value can be accelerated more efficiently. Further, the second heat radiating member 27 based on the priority of some other factor than the cooling efficiency is made to correspond to the second exhaust opening 36 with a relatively low air delivery rate, whereby cooling of the second heating element 23 with a relatively small heating value can be rationalized. Thus, it can be said that the cooling efficiency, manufacturing cost, weight, etc., of the entire portable computer 1 can be optimized.

### Second Embodiment

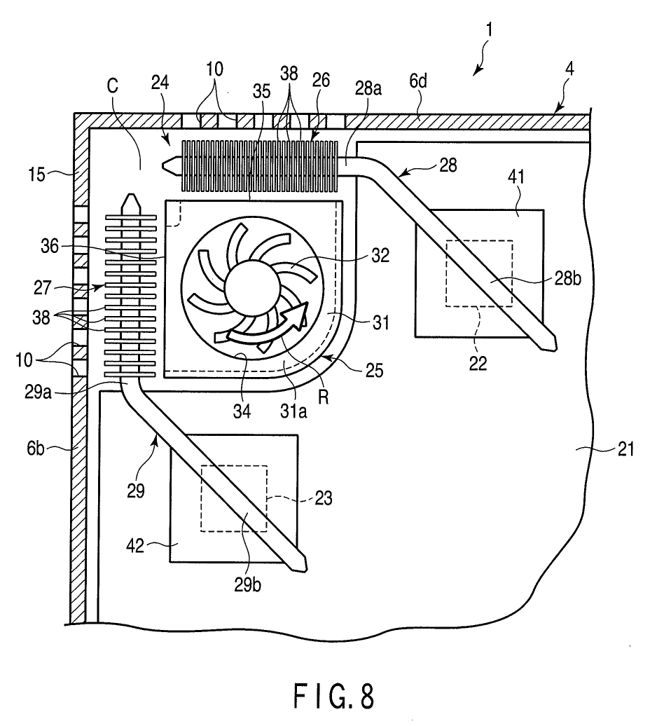

A portable computer 1 as an electronic apparatus according to a second embodiment of the present invention will now be described with reference to FIG. 8. Like numbers are used to designate configurations with like or similar functions to those of the configurations of the first embodiment, and a description of those configurations is omitted.

As shown in FIG. 8, a left-hand cooling fan 25 is located, for example, in a corner portion C in a housing 4 that is defined by a rear wall portion 6d and a left sidewall portion 6b of the housing 4. A first exhaust opening 35 of the fan 25 is opposed to air vents 10 in the rear wall portion 6d of the housing 4. A second exhaust opening 36 of the fan 25 is opposed to air vents 10 in the left sidewall portion 6b of the housing 4.

A first heat radiating member 26 is thermally connected to a first heating element 22 through a first heat transfer member 28. The radiating member 26 is located between the first exhaust opening 35 of the cooling fan 25 and the air vents 10 in the rear wall portion 6d and opposed to the first exhaust opening 35 of the fan 25. A second heat radiating member 27 is thermally connected to a second heating element 23 through a second heat transfer member 29. The radiating member 27 is located between the second exhaust opening 36 of the cooling fan 25 and the air vents 10 in the left sidewall portion 6b and opposed to the second exhaust opening 36 of the fan 25. Other configurations of the portable computer 1 than those described above are the same as those of the first embodiment.

According to the portable computer 1 constructed in this manner, as in the first embodiment, the capacity of the cooling fan 25 can be utilized more efficiently, and a high cooling performance can be achieved.

Since the first exhaust opening 35 is opened wider and higher in air delivery rate than the second exhaust opening 36, it is generally liable to produce much noise. If the first exhaust opening 35 is opposed to the air vents 10 in the rear wall portion 6d of the housing 4, much of noise leaked through the first exhaust opening 35 is released through the air vents 10 in the rear wall portion 6d. Some of the noise released through the air vents 10 in the rear wall portion 6d is intercepted by a display unit 3 and cannot easily reach the user's ears.

Thus, in the portable computer 1 provided with the display unit 3 that is raised on a main unit 2, the cooling fan 25 is mounted with its first exhaust opening 35 opposed to the air vents 10 in the rear wall portion 6d. In the case compared with the cooling fan in which the first exhaust opening 35 is opposed to the air vents 10 in the left sidewall portion 6b, portable computer 1 of the present embodiment produces lower noise, as perceived by the user, so that its noise properties are better.

### Third Embodiment

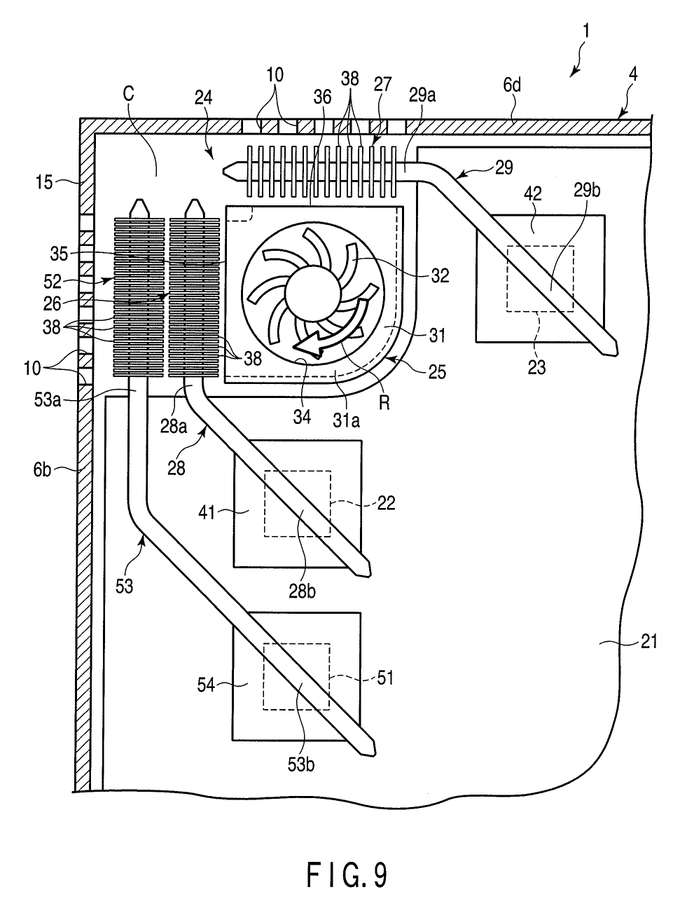

A portable computer 1 as an electronic apparatus according to a third embodiment of the present invention will now be described with reference to FIG. 9. Like numbers are used to designate configurations with like or similar functions to those of the configurations of the first embodiment, and a description of those configurations is omitted.

As shown in FIG. 9, a third heating element 51 is mounted on a circuit board 21. The third heating element 51 is an electronic component that generates heat when activated. A CPU, graphic chip, north bridge, or memory is a specific example of the heating element 51. The heating element stated herein is not limited to this example, but may be any of various components that are expected to generate heat.

A cooling device 24 includes a third heat radiating member 52 and a third heat transfer member 53 that are contained in a housing 4. The third heat radiating member 52 is a fin unit that includes, for example, a plurality of fins 38. As shown in FIG. 9, the third heat radiating member 52 is located side by side with a first heat radiating member 26 between a first exhaust opening 35 of a cooling fan 25 and air vents 10 in a sidewall portion 6b of the housing 4, and opposed to the first exhaust opening 35 of the fan 25.

A third heat receiving member 54 is thermally connected to the third heating element 51. The third heat transfer member 53 extends between the third heat radiating member 52 and the third heating element 51. More specifically, the third heat transfer member 53 includes a heat radiating portion 53a and a heat receiving portion 53b, which are connected to the third heat radiating member 52 and the third heat receiving member 54, respectively.

Thus, the third heat radiating member 52 is thermally connected to the third heating element 51 through the third heat transfer member 53. The third heat transfer member 53 receives, at its heat receiving portion 53b, some of the heat generated by the third heating element 51, and transfers the received heat to the third heat radiating member 52. The third heat transfer member 53 is, for example, a heat pipe. Other configurations of the portable computer 1 than those described above are the same as those of the first embodiment.

According to the portable computer 1 constructed in this manner, as in the first embodiment, the capacity of the cooling fan 25 can be utilized more efficiently, and a high cooling performance can be achieved.

In the case where the third heat radiating member 52 is provided, its cooling efficiency can be increased by opposing it to the first exhaust opening 35, not to the second exhaust opening 36. Thus, the capacity of the cooling fan 25 can be utilized more efficiently, and a high cooling performance can be achieved. For example, the first and third heat radiating members 26 and 52 may be formed integrally with each other.

The following is a description of a group of embodiments of the present invention. An electronic apparatus according to each of the following embodiments is provided with a housing, a heating element mounted in the housing, a cooling fan contained in the housing and provided with a fan case and a fan blade configured to rotate in the fan case, a first heat radiating member contained in the housing, a second heat radiating member contained in the housing, and a heat transfer member extending between the heating element and the first and second heat radiating members. The fan case of the cooling fan includes two adjacent side surface portions and first and second exhaust openings separately provided in the two side surface portions. The first exhaust opening and the second exhaust opening are arranged in a rotational direction of the fan blade in the order named. The first heat radiating member is opposed to the first exhaust opening of the cooling fan. The second heat radiating member is opposed to the second exhaust opening of the cooling fan. The heat transfer member extends from the heating element toward the first heat radiating member and the second heat radiating member and is connected to the first heat radiating member and the second heat radiating member in the order named.

### Fourth Embodiment

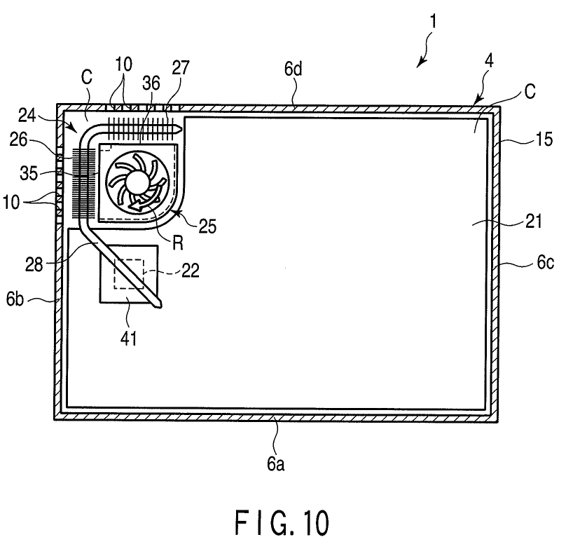

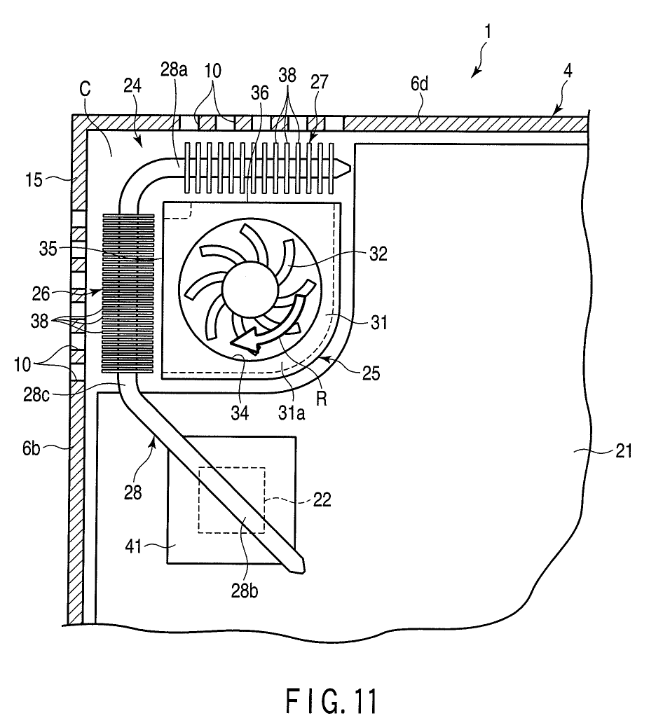

A portable computer 1 as an electronic apparatus according to a fourth embodiment of the present invention will now be described with reference to FIGS. 10 and 11. Like numbers are used to designate configurations with like or similar functions to those of the configurations of the first embodiment, and a description of those configurations is omitted.

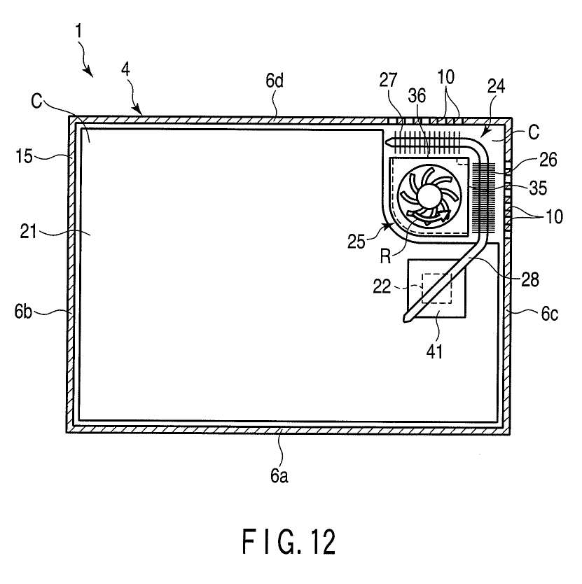

A heating element 22 is mounted on a circuit board 21. A cooling device 24 includes a cooling fan 25, first and second heat radiating members 26 and 27, and a heat transfer member 28 that are contained in a housing 4. The portable computer 1 provided with the right-hand cooling fan 25 according to the present embodiment will now be representatively described in detail with reference to FIGS. 10 and 11. FIG. 12 shows a modification of the present embodiment provided with the left-hand cooling fan 25. The same function and effect of the portable computer 1, which will be described later, can also be obtained with this arrangement.

As shown in FIG. 10, the cooling fan 25 is located, for example, in a corner portion C in the housing 4 that is defined by a rear wall portion 6d and a left sidewall portion 6b of the housing 4. A first exhaust opening 35 of the fan 25 is opposed to air vents 10 in the sidewall portion 6b of the housing 4. A second exhaust opening 36 of the fan 25 is opposed to air vents 10 in the rear wall portion 6d of the housing 4.

As shown in FIG. 11, the first heat radiating member 26 is located between the first exhaust opening 35 of the cooling fan 25 and the air vents 10 in the sidewall portion 6b and opposed to the first exhaust opening 35 of the fan 25. The second heat radiating member 27 is located between the second exhaust opening 36 of the fan 25 and the air vents 10 in the rear wall portion 6d and opposed to the second exhaust opening 36 of the fan 25.

The first heat radiating member 26 is lower in, for example, heat resistance than the second heat radiating member 27. The first and second heat radiating members 26 and 27 are fin units that each include, for example, a plurality of fins 38. The fins 38 of the first heat radiating member 26 are arranged, for example, at pitches narrower than those of the second heat radiating member 27.

As shown in FIG. 11, a heat receiving member 41 is thermally connected to the heating element 22. The heat transfer member 28 extends between the first heating element 22 and the first and second heat radiating members 26 and 27. More specifically, the heat transfer member 28 extends from the heating element 22 toward the first and second heat radiating members 26 and 27 and is connected to the first heat radiating member 26 and the second heat radiating member 27 in the order named.

Thus, the heat transfer member 28 extends from the heating element 22 to an area in front of the first exhaust opening 35 of the cooling fan 25 and is connected to the first heat radiating member 26. The heat transfer member 28 then further extends to an area in front of the second exhaust opening 36 and is connected to the second heat radiating member 27.

The heat transfer member 28 includes a first heat radiating portion 28c connected to the first heat radiating member 26, a second heat radiating portion 28a connected to the second heat radiating member 27, and a heat receiving portion 28b connected to the heat receiving member 41. The first heat radiating portion 28c is situated nearer to the heat receiving portion 28b than the second heat radiating portion 28a is.

The heat transfer member 28 receives, at its heat receiving portion 28b, some of the heat generated by the heating element 22, and transfers the received heat toward the first and second heat radiating portions 28c and 28a. The heat transfer member 28 is, for example, a heat pipe. Other configurations of the portable computer 1 than those described above are the same as those of the first embodiment.

The following is a description of the operation of the portable computer 1.

When the portable computer 1 is activated, the heating element 22 generates heat. Much of the heat generated by the heating element 22 is transferred to the first and second heat radiating members 26 and 27 by the heat transfer member 28.

The first and second exhaust openings 35 and 36 of the cooling fan 25 are arranged in the rotational direction of fan blades 32 in the order named. Therefore, cooling of the first heat radiating member 26 that is opposed to the first exhaust opening 35 can be accelerated more easily than that of the second heat radiating member 27 opposed to the second exhaust opening 36.

The portable computer 1 constructed in this manner is capable of operating a high cooling performance. Specifically, in the portable computer 1, the first heat radiating member 26 that is thermally connected to the heating element 22 at a relatively short distance is opposed to the first exhaust opening 35, of the first and second exhaust openings 35 and 36 that are arranged in the rotational direction of the fan blades 32 in the order named. Further, the second heat radiating member 27 that is thermally connected to the heating element 22 at a relatively long distance is opposed to the second exhaust opening 36.

Thus, the first heat radiating member 26 that can be relatively easily heated to a high temperature is made to correspond to the first exhaust opening 35 with a relatively high air delivery rate, while the second heat radiating member 27 that cannot be relatively easily heated to a high temperature is made to correspond to the second exhaust opening 36 with a relatively low air delivery rate. By doing this, the capacity of the cooling fan 25 can be utilized more efficiently, and the cooling efficiency of the portable computer 1 as a whole can be optimized. In consequence, the portable computer 1 can achieve a high cooling performance.

If the first heat radiating member 26 is lower in heat resistance than the second heat radiating member 27, a relatively large air delivery through the first exhaust opening 35 can be used more effectively, and the capacity of the cooling fan 25 can be utilized more efficiently. Thus, the portable computer 1 can achieve a higher cooling performance. The first and second heat radiating members of the present invention are not limited to this arrangement, and various heat radiating members can be adopted in the same manner as in the first embodiment.

According to the one embodiment of the present invention, from another point of view, the first heat radiating member 26 with a preferentially increased cooling efficiency is made to correspond to the first exhaust opening 35 with a relatively high air delivery rate, whereby cooling of the first heating element 22 with a relatively large heating value can be accelerated more efficiently. Further, the second heat radiating member 27 based on the priority to some other factor than the cooling efficiency is made to correspond to the second exhaust opening 36 with a relatively low air delivery rate, whereby cooling of the second heating element 23 with a relatively small heating value can be rationalized. Thus, it can be said that the cooling efficiency, manufacturing cost, weight, etc., of the entire portable computer 1 can be optimized.

### Fifth Embodiment

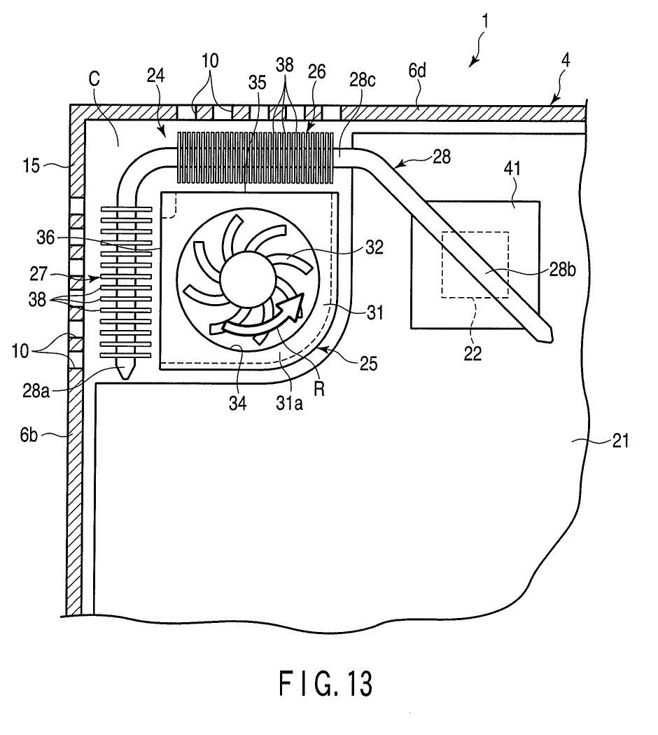

A portable computer 1 as an electronic apparatus according to a fifth embodiment of the present invention will now be described with reference to FIG. 13. Like numbers are used to designate configurations with like or similar functions to those of the configurations of the first, second, and fourth embodiment, and a description of those configurations is omitted.

As shown in FIG. 13, a left-hand cooling fan 25 is located, for example, in a corner portion C in a housing 4 that is defined by a rear wall portion 6d and a left sidewall portion 6b of the housing 4. A first exhaust opening 35 of the fan 25 is opposed to air vents 10 in the rear wall portion 6d of the housing 4. A second exhaust opening 36 of the fan 25 is opposed to air vents 10 in the sidewall portion 6b of the housing 4.

A heat transfer member 28 extends between a heating element 22 and first and second heat radiating members 26 and 27. The heat transfer member 28 extends from the heating element 22 toward the first and second heat radiating members 26 and 27 and is connected to the first heat radiating member 26 and the second heat radiating member 27 in the order named. The first heat radiating member 26 is located between the first exhaust opening 35 of the cooling fan 25 and the air vents 10 in the rear wall portion 6d and opposed to the first exhaust opening 35 of the fan 25. The second heat radiating member 27 is located between the second exhaust opening 36 of the fan 25 and the air vents 10 in the sidewall portion 6b and opposed to the second exhaust opening 36 of the fan 25. Other configurations of the portable computer 1 than those described above are the same as those of the fourth embodiment.

According to the portable computer 1 constructed in this manner, as in the fourth embodiment, the capacity of the cooling fan 25 can be utilized more efficiently, and a high cooling performance can be achieved. Further, some of noise released through the air vents 10 in the rear wall portion 6d is intercepted by a display unit 3 and cannot easily reach the user's ears. Thus, the portable computer 1 according to the present embodiment, like that of second embodiment, produces a lower noise, as perceived by the user, than that of the fourth embodiment, so that its noise properties are better.

### Sixth Embodiment

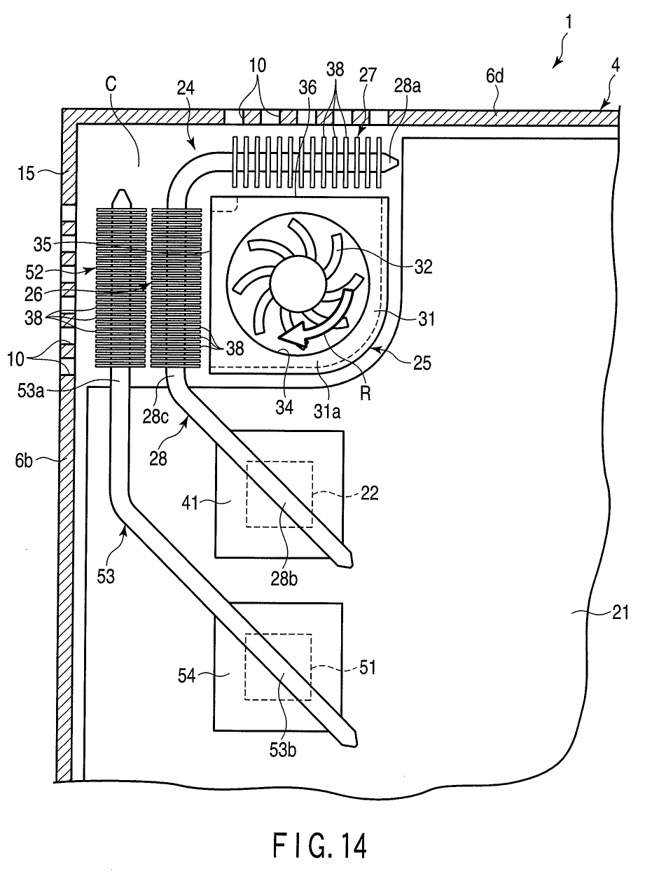

A portable computer 1 as an electronic apparatus according to a sixth embodiment of the present invention will now be described with reference to FIG. 14. Like numbers are used to designate configurations with like or similar functions to those of the configurations of the first, third, and fourth embodiment, and a description of those configurations is omitted.

The portable computer 1 is provided with a second heating element 51, a third heat radiating member 52, and a second heat transfer member 53, in addition to a first heating element 22, first and second heat radiating members 26 and 27, and a first heat transfer member 28. The second heating element 51 is an example of another heating element according to the present invention, which is mounted on a circuit board 21. The third heat radiating member 52 is an example of another heat radiating member according to the invention. The second heat transfer member 53 is an example of another heat transfer member according to the invention. The third heat radiating member 52 and the second heat transfer member 53 are contained in a housing 4.

The third heat radiating member 52 is a fin unit that includes, for example, a plurality of fins 38. As shown in FIG. 14, the third heat radiating member 52 is located side by side with the first heat radiating member 26 between a first exhaust opening 35 of a cooling fan 25 and air vents 10 in a sidewall portion 6b of the housing 4, and opposed to the first exhaust opening 35 of the fan 25. Other configurations of the portable computer 1 than those described above are the same as those of the fourth embodiment.

According to the portable computer 1 constructed in this manner, as in the fourth embodiment, the capacity of the cooling fan 25 can be utilized more efficiently, and a high cooling performance can be achieved. According to the portable computer 1 of the present embodiment, as in the third embodiment, moreover, the capacity of the cooling fan 25 can be utilized more efficiently, and a high cooling performance can be achieved. Further, the first and third heat radiating members 26 and 52 may be formed integrally with each other, for example.

Although the portable computers 1 according to the first to sixth embodiments of the present invention have been described herein, the invention is not limited to those embodiments. The present invention may be variously changed or modified without departing from its spirit or scope.

In each of the second and third embodiments, for example, the cooling fan 25 may alternatively be located in a corner portion C that is defined by the right sidewall portion 6c and the rear wall portion 6d of the housing 4, as in the modification of the first embodiment shown in FIG. 7. Also, in each of the fifth and sixth embodiments, the cooling fan 25 may alternatively be located in a corner portion C that is defined by the right sidewall portion 6c and the rear wall portion 6d of the housing 4, as in the modification of the fourth embodiment shown in FIG. 12.

The number of heating elements is not limited to the cases of the foregoing embodiments. For example, a plurality of heating elements may be thermally connected to one heat transfer member. The heat transfer members 28, 29 and 53 are not limited to the heat pipes, and may alternatively be, for example, metallic plate members. The heat radiating members 26, 27 and 52 are not limited to the fin units, and may alternatively be heat radiating plates.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing;
a first electronic component that produces heat mounted in the housing;
a second electronic component that produces heat mounted in the housing;
a cooling fan in the housing provided with a fan case and a fan blade configured to rotate in the fan case;
a first heat radiator in the housing;
a second heat radiator in the housing;
a first heat conductor extending between the first heat radiator and the first electronic component that produces heat; and
a second heat conductor extending between the second heat radiator and the second electronic component that produces heat,
the fan case of the cooling fan comprising two adjacent side surface portions and first and second openings separately provided in the two side surface portions, the first opening and the second opening being arranged in a rotational direction of the fan blade in a named order,
an amount of heat configured to be produced by the first electronic component that produces heat is greater than an amount of heat configured to be produced by the second electronic component that produces heat,
the first heat radiator being thermally connected to the first electronic component that produces heat through the first heat conductor and opposed to the first opening of the cooling fan,
the second heat radiator being thermally connected to the second electronic component that produces heat through the second heat conductor and opposed to the second opening of the cooling fan.

2. The electronic apparatus of claim 1 wherein a heat resistance value of the first heat radiator is smaller than a heat resistance value of the second heat radiator.

3. The electronic apparatus of claim 1, wherein the first heat radiator and the second heat radiator comprise a plurality of fins, the fins of the first heat radiator being arranged at pitches narrower than those of the second heat radiator.

4. The electronic apparatus of claim 1, further comprising:
a hinge on a first end portion of the housing; and
a display supported on the housing by the hinge and configured to be set between a first posture in which the display is laid to cover the housing and a second posture in which the display is raised with respect to the housing, wherein
the housing comprises a rear wall and a sidewall configured to lie next to the rear wall and to define a corner in the housing with the rear wall, the rear wall and the sidewall being provided with an air vent, and
the cooling fan is located in the corner, the first opening is opposed to the air vent of the rear wall, and the second opening is opposed to the air vent of the sidewall.

5. The electronic apparatus of claim 1, further comprising:
a third electronic component that produces heat in the housing;
a third heat radiator in the housing; and
a third heat conductor extending between the third heat radiator and the third electronic component that produces heat, wherein
the third heat radiator is located next to the first heat radiator and opposed to the first opening of the cooling fan.

6. An electronic apparatus comprising:
a housing;
an electronic component that produces heat in the housing;
a cooling fan in the housing and provided with a fan case and a fan blade configured to rotate in the fan case;
a first heat radiator in the housing;
a second heat radiator in the housing; and
a heat conductor extending between the electronic component that produces heat and the first and second heat radiators,
the fan case of the cooling fan comprising two adjacent side surface portions and first and second openings separately provided in the two side surface portions, the first opening and the second opening being arranged in a rotational direction of the fan blade in a named order,
the first heat radiator being opposed to the first opening of the cooling fan,
the second heat radiator being opposed to the second opening of the cooling fan,
the heat conductor extending from the electronic component that produces heat toward the first heat radiator and the second heat radiator and being connected to the first heat radiator and the second heat radiator in a named order.

7. The electronic apparatus of claim 6, wherein a heat resistance value of the first heat radiator is smaller than a heat resistance value of the second heat radiator.

8. The electronic apparatus of claim 6, wherein the first heat radiator and the second heat radiator comprise a plurality of fins, the fins of the first heat radiator being arranged at pitches narrower than those of the second heat radiator.

9. The electronic apparatus of claim 6, further comprising:
a hinge provided on a first end portion of the housing; and
a display supported on the housing by the hinge and configured to be set between a first posture in which the display is laid to cover the housing and a second posture in which the display is raised with respect to the housing, wherein
the housing comprises a rear wall and a sidewall configured to lie next to the rear wall and to define a corner in the housing with the read wall, the rear wall and the sidewall being provided with an air vent,
the cooling fan is located in the corner, the first opening is opposed to the air vent of the rear wall, and the second opening is opposed to the air vent of the sidewall.

10. The electronic apparatus of claim 6, further comprising:
a second electronic component that produces heat in the housing;
a third heat radiator in the housing; and
a heat conductor extending between the third heat radiator and the second electronic component that produces heat,
the third heat radiator being located next to the heat radiator and opposed to the first opening of the cooling fan.
